(19) United States
(12) Patent Application Publication
(10) Pub. No.: US 2016/0043529 A1
(43) Pub. Date: Feb. 11, 2016

(54) MONOLITHICALLY INTEGRATED SURFACE EMITTING LASER WITH MODULATOR

(71) Applicant: Tokyo Institute of Technology, Tokyo (JP)

(72) Inventors: Fumio Koyama, Tokyo (JP); Dalir Hamed, Tokyo (JP)

(21) Appl. No.: 14/818,407

(22) Filed: Aug. 5, 2015

(30) Foreign Application Priority Data
Aug. 8, 2014 (JP) 2014-162088

(51) Int. Cl. H01S 5/183; H01S 5/10; H01S 5/187

(52) U.S. Cl. CPC H01S 5/18311; H01S 5/187; H01S 5/18302; H01S 5/1014

(57) ABSTRACT

A surface emitting laser includes a structure in which a semiconductor substrate, a lower DBR, and an active layer are layered. A VCSEL (vertical cavity surface emitting laser) and an EAM (electro-absorption modulator) are formed adjacent to each other along a first direction defined on the substrate plane such that they are optically coupled. The EAM outputs an emitted light in a direction that is orthogonal to the substrate. The width of a waveguide region of the VCSEL defined in the second direction is narrower than the width of a waveguide region of the EAM.

### CROSS-REFERENCE TO RELATED APPLICATIONS

This application is based upon and claims the benefit of priority from the prior Japanese Patent Application No. 2014-162088, filed Aug. 8, 2014, now granted as Japanese Patent No. 5721246, the entire contents of which are incorporated herein by reference.

### BACKGROUND OF THE INVENTION

1. Field of the Invention

The present invention relates to a surface emitting semiconductor laser.

2. Description of the Related Art

As a key device for optical data communication, a light source which operates with low power consumption at a very high data rate is required. As such a light source, the vertical cavity surface emitting laser (which will also be referred to as a “VCSEL” hereafter) plays an important role. Recently, an operation speed of the VCSEL is improved and the speed reaches 25 Gbps, however a faster speed is required. Furthermore, development is being advanced for an arrangement in which a modulator is integrated on the VCSEL. However, it cannot be said that such arrangements have met the requirements of the market from the viewpoint of modulation rate. Thus, development is being advanced worldwide for such arrangements having a further increased data rate.

FIG. 1 is a cross-sectional view of a surface emitting laser with an optical modulation function using a VCSEL disclosed in Non-patent document 1 to a comparison technique. An surface emitting laser 100r includes a VCSEL 200 and an electro-absorption modulator (which will also be referred to as “EAM” hereafter) 300 layered in the vertical direction. The VCSEL 200 includes a GaAs (gallium arsenide) substrate 204, a lower distributed Bragg reflector (which will also be referred to as “DBR” hereafter) 206, a selectively-oxidized layer (current confinement layer) 208, an active layer 210, an upper DBR 212, and a driving electrode 214. When DC current is supplied via the driving electrode 214, the active layer 210 is exited, and light is emitted. Such an arrangement provides multiple reflection of the emitted light between the lower DBR 206 and the upper DBR 212 in the direction that is orthogonal to the substrate. Furthermore, the active layer 210 provides stimulated emission, thereby amplifying the emitted light. The upper DBR 212 is designed to have a reflection ratio that is less than 100%, which allows a part of the amplified light to be output via the EAM 300 side.

The EAM 300 is formed on the VCSEL 200, and has the same basic layer structure as that of the VCSEL 200. Specifically, the EAM 300 includes a lower DBR 302, an active layer 304, an upper DBR 306, and a control electrode 308, layered in the vertical direction. By modulating the voltage applied to the control electrode 308, such an arrangement is capable of changing the bandgap of the active layer 304, thereby allowing the transmissivity and light absorption efficiency to be changed. Thus, such an arrangement is capable of modulating (switching) the intensity of the emitted light 102.

### RELATED ART DOCUMENTS

### Patent Document 1

Japanese Patent Application Laid-Open No. H11-274640

### Patent Document 2

Japanese Patent Application Laid Open No. 2007-189033

### Patent Document 3

Japanese Patent Application Laid Open No. 2010-3930

### Patent Document 4

Japanese Patent Application Laid Open No. 2012-49180

### Non-Patent Document 1

Germann et al., “Electro-optical resonance modulation of vertical-cavity surface-emitting lasers”, OPTICS EXPRESS 5102, Vol. 20, No. 4, 13 Feb. 2012.

The surface emitting laser 100r shown in FIG. 1 has a structure in which the VCSEL 200 and the EAM 300 are layered in the vertical direction. This leads to a restriction being placed on the thickness (height) of the EAM 300. That is to say, the EAM 300 is required to have a small thickness. This leads to undesirable optical feedback that is input to the VCSEL 200 from the EAM 300. With such an arrangement, in a case in which the light absorption efficiency of the EAM 300 is modulated, this leads to a change in the intensity of the optical feedback input to the

VCSEL 200. This leads to fluctuation of the light intensity in the VCSEL 200 over time, although it should be maintained at a constant level. This leads to noise and/or a reduction in the modulation rate of the surface emitting laser 100r.

### SUMMARY OF THE INVENTION

In order to solve such a problem, the present inventors have proposed an surface emitting laser having a configuration in which a VCSEL and an EAM 300 are arranged in a horizontal direction of the substrate (see Patent document 4).

The present invention has been made in view of such a situation. Accordingly, it is an exemplary purpose of an embodiment of the present invention to provide an surface emitting laser which operates with an high modulation rate and/or reduced noise by improving the coupling between VCSEL and EAM.

An embodiment of the present invention relates to an surface emitting laser. The surface emitting laser comprises: a semiconductor substrate; a lower distributed Bragg reflector formed on the semiconductor substrate; an active layer formed on the lower distributed Bragg reflector; and an upper distributed Bragg reflector formed on the active layer. A vertical cavity surface emitting laser and an electro-absorption modulator are formed adjacent to each other along a first direction defined on the substrate plane such that they are optically coupled. The modulator outputs an emitted light in a direction that is orthogonal to the substrate. The width of the vertical cavity surface emitting laser, defined in a second direction that is orthogonal to the first direction defined on the substrate plane, is narrower than the width of the electro-absorption modulator.

The laser light generated by the vertical cavity surface emitting laser propagates at a low speed in the first direction (slow light) while being reflected multiple times between the upper DBR and the lower DBR. Typically, optical coupling easily occurs when light passes from a region having a narrow width to a region having a wide width. Conversely, optical coupling does not easily occur when light passes from a region having a wide width to a region having a narrow width. Thus, by configuring the waveguide region of the vertical cavity surface emitting laser to have a width that is narrower in the second direction than the width of the waveguide region of the electro-absorption modulator in the second direction, such an arrangement is capable of suppressing optical feedback from the electro-absorption modulator to the vertical cavity surface emitting laser while providing ease of optical coupling for light input from the vertical cavity surface emitting laser to the electro-absorption modulator. This suppresses fluctuation of the light intensity in the vertical cavity surface emitting laser. Thus, such an arrangement provides an improved modulation rate, as well as or in addition to reduced noise.

In the vertical cavity surface emitting laser, transverse modes may be formed using reflection that occurs on a face that connects the vertical cavity surface emitting laser and the electro-absorption modulator.

The output may be taken from the end portion of the electro-absorption modulator, and the top reflectivity may be lower than that in the other sections.

Also, the waveguide region of the electro-absorption modulator may be configured as a multi-mode interference waveguide region. Also, the length of the electro-absorption modulator defined in the first direction may be determined such that optical feedback to the vertical cavity surface emitting laser, due either to reflections from features internal to the device or to reflections from surfaces external to the device, is reduced.

The intensity of optical feedback from the electro-absorption modulator to the vertical cavity surface emitting laser fluctuates in a cyclic manner according to a change in the length of the electro-absorption modulator. Thus, by optimizing the length of the electro-absorption modulator, such an arrangement further suppresses the optical feedback.

Also, the surface emitting laser may further comprise a current confinement layer and/or an index guiding structure, which may or may not be the same as the current confinement layer, in the vicinity of the active layer to confine a carrier injection and guide the light, respectively, in a lateral direction, current and light to be guided. Also, the width of the waveguide region of the vertical cavity surface emitting laser and the width of the waveguide region of the electro-absorption modulator may be determined according to the current confinement layer.

Also, the current confinement layer may be configured as a selectively-oxidized layer comprising an oxidized region selectively oxidized from a side face toward an inner side and an un-oxidized region surrounded by the oxidized region.

Also, a high-resistance region may be formed by means of ion injection as a boundary region that couples the current confinement layer of the vertical cavity surface emitting laser and the current confinement layer of the electro-absorption modulator.

Such an arrangement allows light to propagate from the waveguide region of the vertical cavity surface emitting laser to the waveguide region of the electro-absorption modulator while suppressing the flow of current in the lateral direction.

Also, the surface emitting laser may further comprise a metal mirror formed on the upper distributed Bragg reflector in a region in which the vertical cavity surface emitting laser is formed. Otherwise the surface emitting laser may further comprise a dielectric multi-layer mirror formed on the upper distributed Bragg reflector in a region in which the vertical cavity surface emitting laser is formed.

This allows the upper DBR in the vertical cavity surface emitting laser to have a reflection ratio that is close to 100% and allows the upper DBR in the electro-absorption modulator to have a reflection ratio that is lower than 100% with each being configured to have the same number of layers.

Also, the upper distributed Bragg reflector having a reflectivity of substantially 100% may be pre-formed. In a region where the electro-absorption modulator is formed, number of layers of the upper distributed Bragg reflector may be reduced, for example by etching, such that the top reflectivity at the electro-absorption modulator is less than 100%.

The light may be totally reflected at the end portion of the electro-absorption modulator.

Accordingly, the reflected light is modulated in the electro-absorption modulator and the downsizing of the electro-absorption modulator is achieved. Further, downsizing the device allows the modulation rate to be improved, because the modulation rate is limited by the stray capacitance of the device and the stray capacitance is proportional to the device size.

Also, the waveguide region may have a width that is tapered in the second direction in a region that couples the vertical cavity surface emitting laser and the electro-absorption modulator.

It is to be noted that any arbitrary combination or rearrangement of the above-described structural components and so forth is effective as and encompassed by the present embodiments.

Moreover, this summary of the invention does not necessarily describe all necessary features so that the invention may also be a sub-combination of these described features.

### BRIEF DESCRIPTION OF THE DRAWINGS

Embodiments will now be described, by way of example only, with reference to the accompanying drawings which are meant to be exemplary, not limiting, and wherein like elements are numbered alike in several Figures, in which:

FIG. 1 is a cross-sectional view of an surface emitting laser using a VCSEL according to a comparison technique;

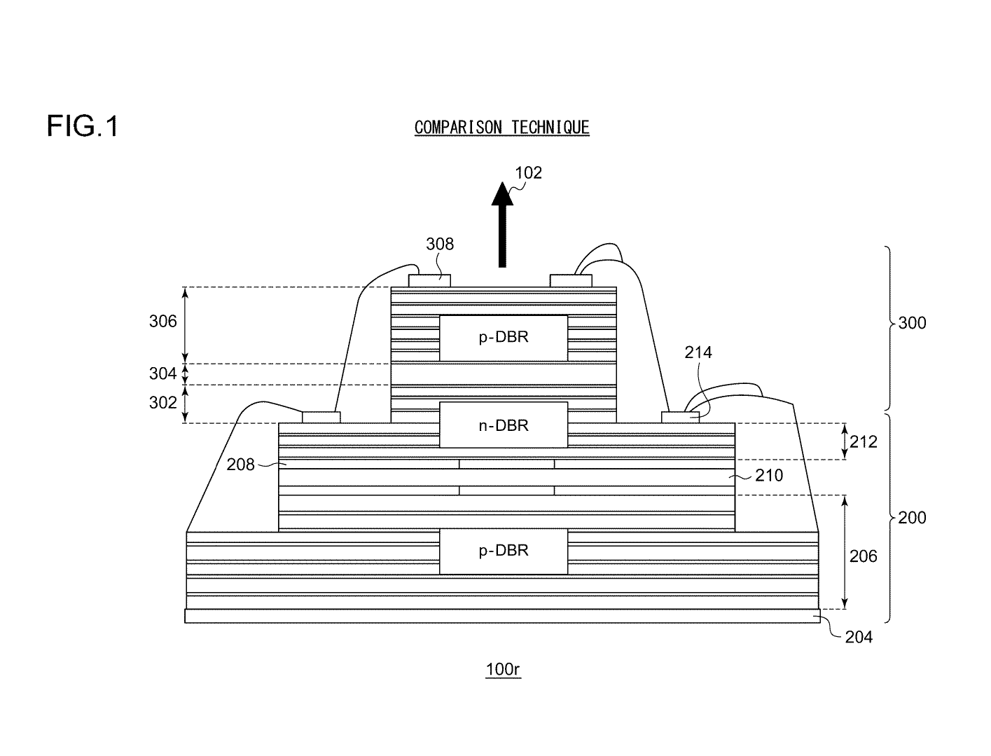

FIG. 2A is a perspective view of an surface emitting laser according to an embodiment, FIG. 2B is a cross-sectional view thereof, and FIG. 2C is a plan view thereof;

FIG. 3A is a graph showing a wave propagation of forward direction, and FIG. 3B is a graph showing a wave propagation of backward direction;

FIG. 4A is an intensity distribution map of the light in the forward direction and FIG. 4B is an intensity distribution map of the light in the backward direction;

FIG. 5 is a diagram showing the relation between the device length L of EAM and the intensity of optical feedback input from the EAM to the VCSEL;

FIG. 6A is a diagram showing the measurement result of the modulated waveform (eye pattern) measured for the surface emitting laser according to the embodiment, and FIG. 6B is a diagram showing the measurement result of the eye pattern measured for a surface emitting laser having no function of suppressing optical feedback;

FIG. 7A is a diagram showing the measurement results for the small-signal modulation characteristics of the surface emitting laser according to the embodiment, and FIG. 7B is a diagram showing the relation between the reciprocal of the length of the EAM, i.e., 1/L, and the 3-dB bandwidth; and

FIG. 8A is a cross-sectional view of an surface emitting laser according to one modification, and FIG. 8B is a plan view thereof.

### DETAILED DESCRIPTION OF THE INVENTION

The invention will now be described based on preferred embodiments which do not intend to limit the scope of the present invention but exemplify the invention. All of the features and the combinations thereof described in the embodiment are not necessarily essential to the invention.

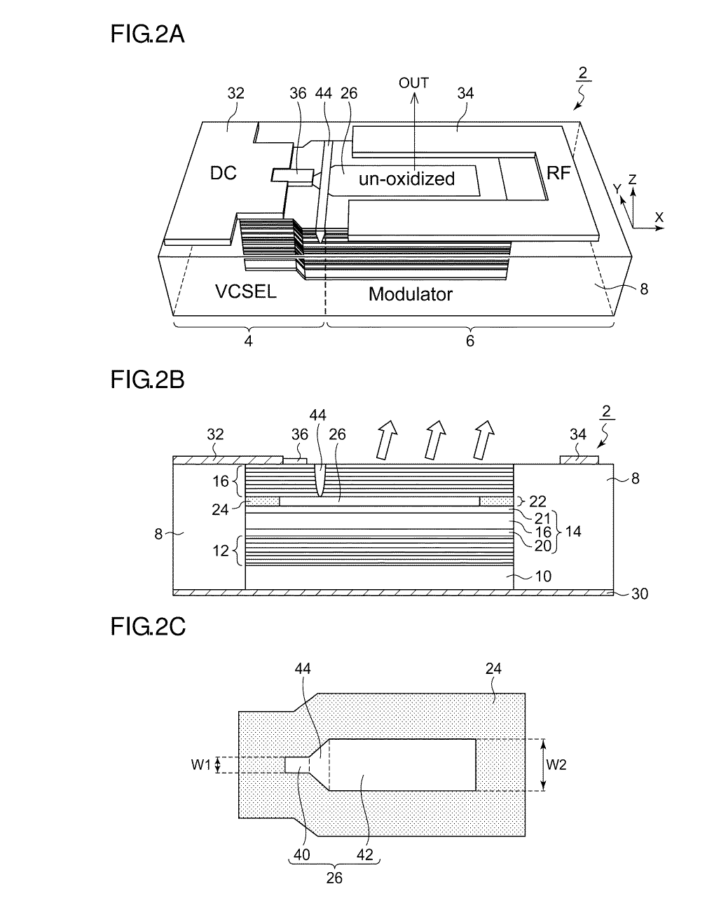

FIG. 2A is a perspective view of an surface emitting laser 100 according to an embodiment. FIG. 2B is a cross-sectional view thereof, and FIG. 2C is a plan view thereof. First, description will be made with reference to FIG. 2B regarding a layer structure of the surface emitting laser 100.

The surface emitting laser (which will also be referred to simply as the “surface emitting laser” hereafter) 2 mainly includes a semiconductor substrate 10, a lower DBR 12, an active layer 14, and an upper DBR 16, formed in the vertical direction. Description will be made in the present embodiment regarding the surface emitting laser 2 configured to generate light at a wavelength of 980 nm, and having components formed of suitable materials having suitable compositions for the wavelength of the emitted light.

The semiconductor substrate 10 is configured as a III-V family semiconductor substrate. In the present embodiment, the semiconductor substrate 10 is configured as a GaAs substrate. An n-side electrode 30 is formed on the back face of the semiconductor substrate 10. The lower DBR 12 has a layer structure in which an A1_{0.92}Ga_{0.08}As layer and an A1_{0.16}Ga_{0.84}As layer, each of which has been doped with silicon as an n-type dopant, are alternately and repeatedly laminated. With the laser emission wavelength as λ, and with the refractive index as nᵣ, each layer is formed with a thickness of λ/4nᵣ. In order to provide a high reflection ratio of almost 100%, these layers are formed for 41.5 periods, for example. After doping with silicon configured as an n-type dopant, each layer has a carrier density of 3×10¹⁸ cm⁻³.

The active layer 14 has a multiple quantum well structure 18 comprising In_{0.2}Ga_{0.8}As/GaAs (indium gallium arsenide/gallium arsenide) layers. The active layer 14 may have a triple quantum well structure, for example. Furthermore, a lower spacer layer 20 and an upper spacer layer 21, each of which is configured as an undoped A1_{0.3}Ga_{0.7}As layer, may be provided to the respective faces of the multiple quantum well structure 18, as necessary. The upper DBR 16 has a layer structure in which carbon-doped A1_{0.92}Ga_{0.08}As layers and A1_{0.16}Ga_{0.84}As layers (aluminum gallium arsenide layers) are formed to a thickness of 26 periods, for example.

A current confinement layer (selectively-oxidized layer) 22 is formed in a region in the vicinity of the active layer 14. For example, the current confinement layer 22 is formed as a bottom layer of the upper DBR 16 or otherwise as an inner layer thereof. The current confinement layer 22 is configured as an Al_{0.98}Ga_{0.02}As layer or otherwise an AlAs layer, for example. The current confinement layer 22 is formed with a higher Al density than those of the lower DBR 12 and the upper DBR 16. Thus, in the mesa oxidizing step, oxidization of the current confinement layer 22 advances with high speed. As a result, the current confinement layer 22 has an outer oxidized region 24 and an inner un-oxidized region 26 surrounded by the outer oxidized region 24. Such a structure allows light, which is to be guided from the VCSEL 4 to the EAM 6, to be confined within the un-oxidized region 26 with respect to the plane direction (lateral direction). Waveguide regions 40 and 42 respectively represent the region of the VCSEL 4 and the region of the EAM 6, each of which is capable of confining light. Furthermore, p-side electrodes are formed on the top layer of the upper DBR 16 such that they function as a driving electrode 32 and a control electrode 34 described later. The p-side electrodes may be configured as a contact layer having a high dopant density of 1×10¹⁹ cm³, for example. The outer circumference of the semiconductor region is sealed with a polymer layer 8.

The above is the cross-sectional structure of the surface emitting laser 2. Next, description will be made with reference to FIGS. 2A and 2C regarding the planar structure of the surface emitting laser 2.

The VCSEL 4 and the EAM 6 are formed adjacent to each other on the substrate plane along the first direction (the X-axis direction in the drawing) such that they are optically coupled with each other. The EAM 6 allows the emitted light to be output in a direction (the Z direction in the drawing) that is orthogonal to the substrate at its entire region. On the substrate plane, a given direction that is orthogonal to the first direction will be referred to as the second direction (the Y-axis direction in the drawing). As shown in FIG. 2C, the surface emitting laser 2 is configured such that the VCSEL 4 includes a waveguide region 40 having a second direction width (which will simply be referred to as the “width” hereafter) W1 that is narrower than the width W2 of the waveguide region 42 of the EAM 6, which is one of the features of the surface emitting laser 2. Specifically, the current confinement layer 22 is formed by selectively oxidizing it such that the un-oxidized region 26 in the VCSEL 4 has the width W1 that is greater than the width W2 of the un-oxidized region 26 in the EAM 6. More specifically, first, the lower DBR 12, the active layer 14, the upper DBR 16, and the like, are laminated on the semiconductor substrate 10 such that they have a width that is smaller in the VCSEL 4 than in the EAM 6. Subsequently, the layer structure is equally oxidized from the outer faces, thereby forming the waveguide regions having different widths (W1<W2).

A high-resistance region 44 having a resistance on the order of 1 MΩ is preferably formed by means of ion (proton) injection as a coupling region that couples the waveguide regions 40 and 42 included in the current confinement layer 22. This allows light to propagate from the waveguide region 40 to the waveguide region 42 while preventing the current from flowing in the lateral direction. In order to provide an upper mirror of the vertical oscillator of the VCSEL 4 with a reflection ratio that is close to 100%, a high-reflection mirror 36 is preferably formed on the top face of the upper DBR 16. The high-reflection mirror 36 is preferably formed of a metal material such as aluminum Al.

The above is the configuration of the surface emitting laser 2. Next, description will be made regarding the operation thereof.

Upon the injection of a DC current via the control electrode 34, laser oscillation is caused within the waveguide region 40 of the VCSEL 4. Subsequently, the laser light thus generated propagates to the waveguide region 42 of the EAM 6. A control voltage (AC voltage) to be used for modulation is applied to the control electrode 34 of the EAM 6 such that it has a polarity that is the reverse of that applied to the driving electrode 32. This allows the absorption ratio of the waveguide region 42 to be changed, thereby modulating the intensity of the output emitted light. As described above, such an arrangement is provided with the high-resistance region 44, thereby suppressing a current leak between the waveguide regions 40 and 42.

Next, description will be made regarding the advantages of the surface emitting laser 2.

The laser light generated by the VCSEL 4 propagates in the first direction (X direction) while being reflected multiple times between the lower DBR 12 and the upper DBR 16. Typically, optical coupling easily occurs when light passes from a region having a narrow width in a direction that is orthogonal to the propagation direction to a region having a wide width in this direction. Conversely, optical coupling does not easily occur when light passes from a region having a wide width to a region having a narrow width. Thus, by designing the width W1 of the waveguide region 40 of the VCSEL 4 to be smaller than the width W2 of the waveguide region 42 of the EAM 6, such an arrangement provides high-efficiency optical coupling for the light that propagates from the VCSEL 4 to the EAM 6 while suppressing optical feedback from the EAM 6 to the VCSEL 4. Such an arrangement allows fluctuation in the light intensity to be reduced in the VCSEL 4. This provides an improved modulation rate and/or reduced noise.

Furthermore, with the surface emitting laser 2, in addition to providing the VCSEL 4 and EAM 6 with the respective waveguide regions having different widths, by optimizing the length L of the EAM 6 in the first direction (which will be referred to simply as the “device length” hereafter), such an arrangement allows the intensity of optical feedback to be reduced.

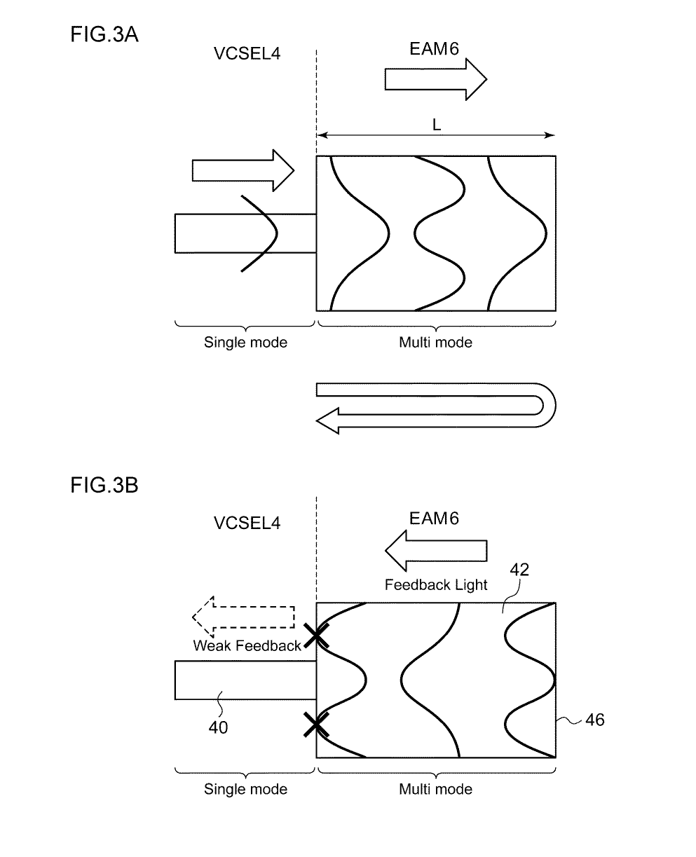

FIG. 3A is a graph showing a wave propagation of forward direction from VCSEL 4 to EAM 6, and FIG. 3B is a graph showing a wave propagation of backward direction from EAM 6 to VCSEL 4. The light oscillated in the single mode in the VCSEL 4 propagates as multi-mode light in the EAM 6. As shown in FIG. 3B, the light input from the VCSEL 4 is reflected by an end face 46 of the EAM 6. On the other hand, the waveguide mode in the EAM 6 changes according to the length L of the waveguide region 42. Thus, by optimizing the length L of the waveguide region 42, such an arrangement allows the optical feedback to the waveguide region 40 to be reduced.

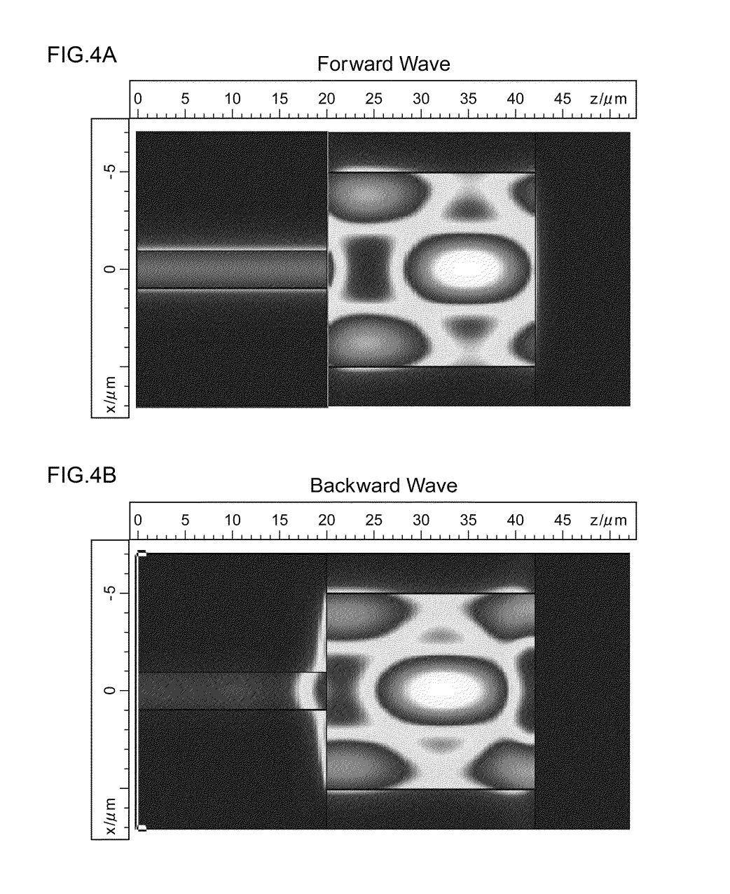

FIG. 4A is an intensity distribution map of the light in the forward direction and FIG. 4B is an intensity distribution map of the light in the backward direction. In the vertical cavity surface emitting laser, transverse modes is formed using reflection that occurs on a face that connects the vertical cavity surface emitting laser and the electro-absorption modulator.

In addition to the difference of the width between the VCSEL 4 and EAM 6, optimizing the device length L of the EAM 6 allows the optical feedback to the VCSEL 4 to be reduced.

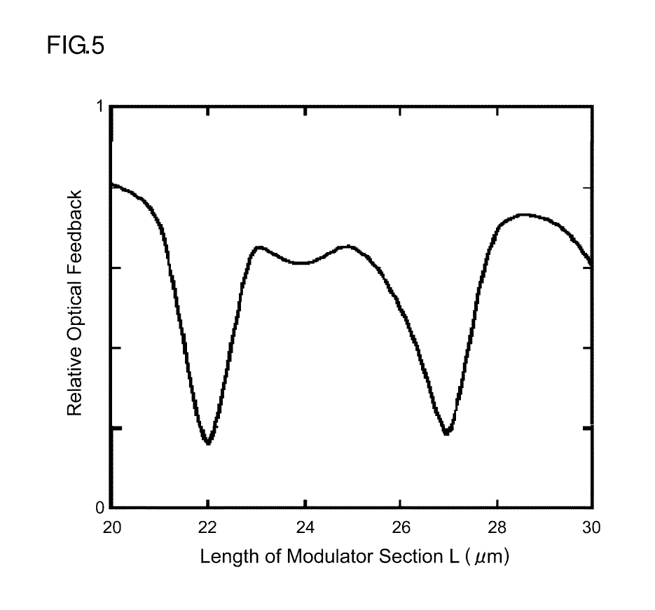

FIG. 5 is a diagram showing the relation between the device length L of the EAM 6 and the intensity of optical feedback input from the EAM 6 to the VCSEL 4. The intensity of the optical feedback fluctuates periodically according to a change in the optical path length 2L. Thus, the optical path length 2L (i.e. the device length L of EAM 6) is preferably designed so as to lessen the intensity of the optical feedback. The optical path length 2L may be optimized by means of electromagnetic field simulation and/or based on experimental data.

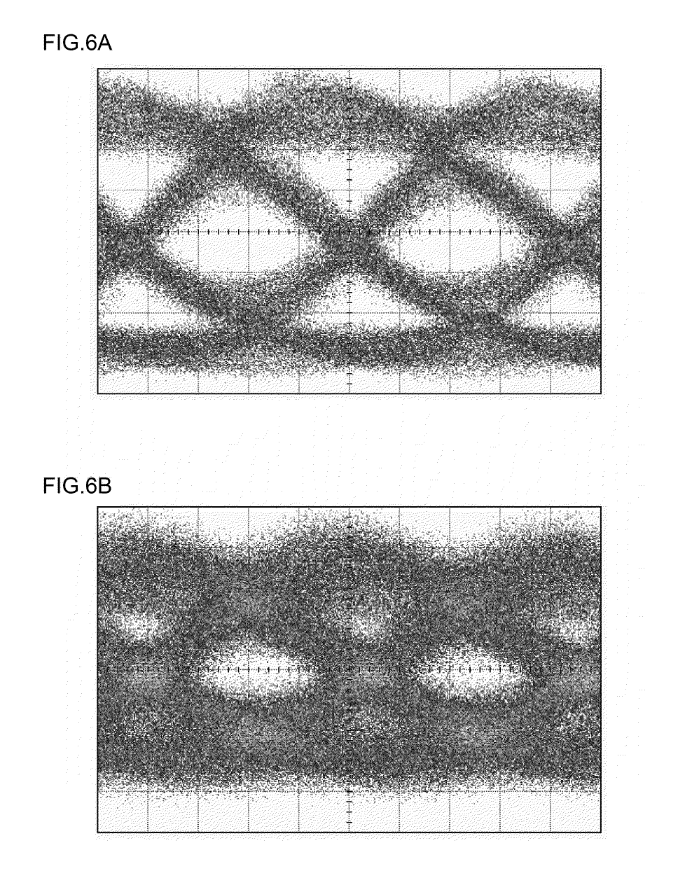

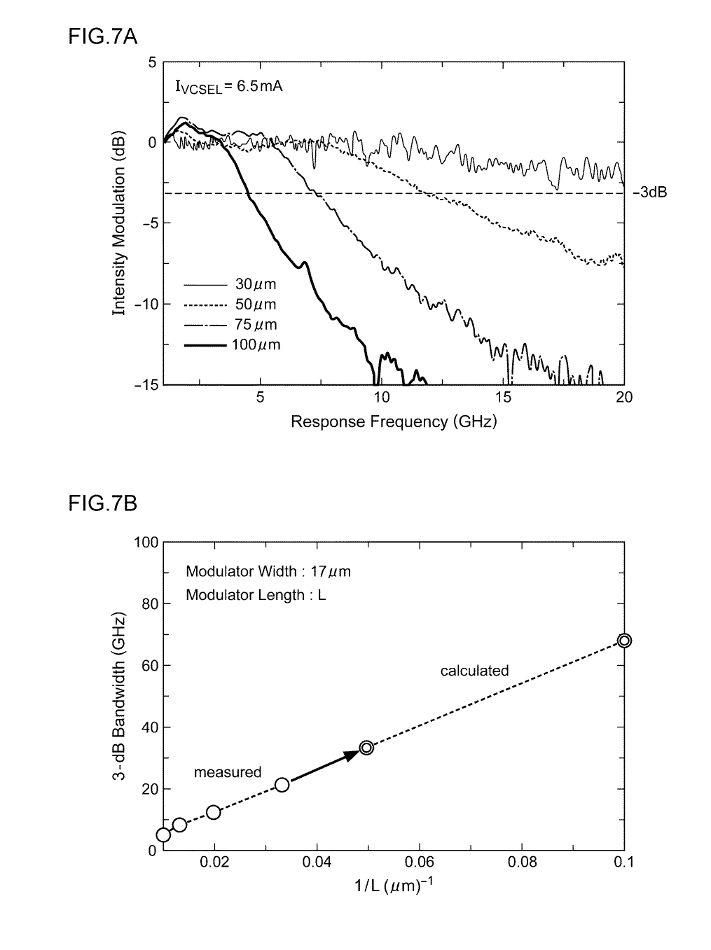

FIG. 6A is a diagram showing the measurement result of the modulated waveform (eye pattern) provided by the surface emitting laser 2 according to the embodiment. As a comparison example, FIG. 6B shows the measurement result of the eye pattern provided by a surface emitting laser having no function of suppressing optical feedback. The measurements were performed at 25 Gbps. It should be noted that the eye pattern shown in FIG. 6B was obtained by measurement of the surface emitting laser disclosed in the Non-patent documents (Dalir et al., APPLIED PHYSICS LETTERS 103, 091109, 2013, and Dalir et al., APPLIED PHYSICS EXPRESS 7, 022102, 2014). This measurement was performed using an NRZ (non-return-to-zero) pseudorandom bit sequence (PBRS) having (2³¹−1) output patterns. The surface emitting laser 2 which was used for the measurement includes the EAM 6 having a length of 50 μm. Such an arrangement has a 3 dB bandwidth at 12 GHz as shown in FIG. 7A, which provides a high extinction ratio (ER) of 4 dB for a PBRS signal having a data rate of 25 Gbps.

As described above, the surface emitting laser 2 according to the embodiment is designed such that the VCSEL 4 has the width W1 that is smaller than the width W2 of the EAM 6 so as to provide reduced optical feedback. In addition, by optimizing the length L of the EAM 6, such an arrangement allows the eye pattern to have an improved aperture ratio, thereby improving the transmission rate.

FIG. 7A is a diagram showing the measurement results for the small-signal modulation characteristics of the surface emitting laser according to the present embodiment. Specifically, four samples were formed including the respective EAMs 6 having the same width W2 of 17 μm and different lengths L. Subsequently, the small-signal modulation characteristics were measured for each sample. The VCSEL 4 was driven using a DC current of 6.5 mA. The output emitted light was collected using a multi-mode fiber. The intensity of the output emitted light was measured using an optical detector having a bandwidth of 25 GHz. The small-signal modulation characteristics were measured using a network analyzer having a bandwidth of 40 GHz. AC voltages of −0.8 V, −0.5 V, −0.5 V, and −0.4 V were applied via the control electrode 34 to samples having lengths L of 30 μm, 50 μm, 70 μm, and 100 μm, respectively. FIG. 7B is a diagram showing the relation between the reciprocal of the length of the EAM 6, i.e., 1/L, and the 3-dB bandwidth. It can be understood that, as the length of the EAM 6 becomes shorter, the 3-dB bandwidth becomes wider. That is to say, it has been confirmed by experiment that the surface emitting laser 2 including the EAM 6 having a relatively small length L is capable of transmitting a signal having a frequency of 25 GHz or more.

Description has been made regarding the present invention with reference to the embodiments using specific terms. However, the above-described embodiments show only the mechanisms and applications of the present invention for exemplary purposes only, and are by no means intended to be interpreted restrictively. Rather, various modifications and various changes in the layout can be made without departing from the spirit and scope of the present invention defined in appended claims.

Description has been made in the embodiment regarding an arrangement in which the un-oxidized region 26 of the current confinement layer 22 has a tapered portion as a boundary between the waveguide regions 40 and 42. However, the present invention is not restricted to such an arrangement. As shown in FIGS. 3A and 3B, the un-oxidized region 26 may have a width that changes in a stepwise manner between the width W1 of the waveguide region 40 and the width W2 of the waveguide region 42.

The oscillation wavelength of the surface emitting laser 2 is not restricted to 980 nm. Thus, it can be understood by those skilled in this art that each component may be formed of suitable materials having suitable compositions according to the oscillation wavelength.

Description has been made in the embodiment regarding an arrangement in which the driving electrode 32 and the control electrode 34 are formed on the top face of the upper DBR 16. However, the present invention is not restricted to such an arrangement. Also, the driving electrode 32 and the control electrode 34 may each be formed within the upper DBR 16 or otherwise on the bottom face thereof.

Description has been made in the embodiment regarding an arrangement where the high-reflection mirror 36 on the upper DBR 16. However, the present invention is not restricted to such an arrangement. In one embodiment, the upper DBR 16 having a reflectivity of substantially 100% is preliminary formed, and in the region 42 where the EAM 6 is formed, number of layers of the upper DBR is reduced, for example by etching, so that the top reflectivity less than 100% at the EAM 6 is achieved, and the output light is taken from this region.

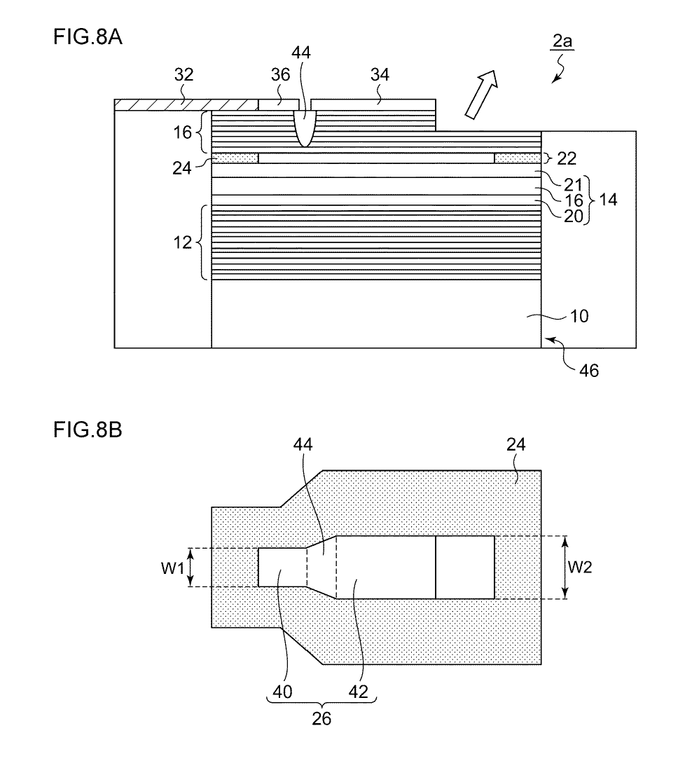

FIG. 8A is a cross-sectional view of an surface emitting laser 2a according to one modification, and FIG. 8B is a plan view thereof. In this modification, the output is taken from the end portion 46 of the EAM 6 with the lower top reflectivity less than that in the other sections. The reflectivity may be lowered by reducing the number of layers of upper DBR 16.

Description has been made in the embodiment regarding an arrangement configured to allow the waveguide region 40 of the VCSEL 4 and the waveguide region 42 of the EAM 6 to confine light in their lateral direction by means of the current confinement layer 22 configured as a selectively-oxidized film. However, the present invention is not restricted to such an arrangement. Examples of other approaches for the current confinement that have been proposed include: a method using ion injection (Zeeb et al. “Planar Proton Implanted VCSEL's and Fiber-Coupled 2-D VCSEL Arrays”, IEEE JOURNAL OF SELECTED TOPICS IN QUANTUM ELECTRONICS, VOL. 1. NO. 2, June 1995); a method using a tunnel pn junction and crystal regrowth (Ortsiefer et al. “Low-threshold index-guided 1.5 m long-wavelength vertical-cavity surface-emitting laser with high efficiency”, APPLIED PHYSICS LETTERS, VOL. 76, NO. 16, February 2000); and a method using a process for forming a mixed-crystal quantum well structure (Sugawara et al., “Laterally intermixed quantum structure for carrier confinement in vertical-cavity surface-emitting lasers”, ELECTRONICS LETTERS, VOL. 45, NO. 3, January 2009). Any one of such techniques may be employed. Otherwise, known or prospectively available techniques may be employed.

In one embodiment, in addition to, or instead of the current confinement layer 22, an index guiding structure which guides the light is formed in the vicinity of the active layer. The index guiding structure may or may not be the same as the current confinement layer 22.

While the preferred embodiments of the present invention have been described using specific terms, such description is for illustrative purposes only, and it is to be understood that changes and variations may be made without departing from the spirit or scope of the appended claims.

What is claimed is:

1. An surface emitting laser comprising:
a semiconductor substrate;
a lower distributed Bragg reflector formed on the semiconductor substrate;
an active layer formed on the lower distributed Bragg reflector; and
an upper distributed Bragg reflector formed on the active layer,
wherein a vertical cavity surface emitting laser and an electro-absorption modulator are formed adjacent to each other along a first direction defined on the substrate plane such that they are optically coupled,
and wherein a width of a waveguide region included in the vertical cavity surface emitting laser, defined in a second direction that is orthogonal to the first direction defined on the substrate plane, is narrower than a width of a waveguide region of the electro-absorption modulator defined in the second direction,
and wherein the electro-absorption modulator outputs an emitted light in a direction that is orthogonal to the substrate.

2. The surface emitting laser according to claim 1, wherein, in the vertical cavity surface emitting laser, transverse modes are formed using reflection that occurs on a face that connects the vertical cavity surface emitting laser and the electro-absorption modulator.

3. The surface emitting laser according to claim 1, wherein, the output is taken from the end portion of the electro-absorption modulator, wherein, the top reflectivity is lower than that in the other sections.

4. The surface emitting laser according to claim 1, wherein the waveguide region of the electro-absorption modulator is configured as a multi-mode interference waveguide region,
and wherein the length of the electro-absorption modulator defined in the first direction is determined such that optical feedback to the vertical cavity surface emitting laser, due either to reflections from features internal to the device or to reflections from surfaces external to the device, is reduced is reduced.

5. The surface emitting laser according to claim 1, further comprising a current confinement layer and/or an index guiding structure which may or may not be the same as the current confinement layer, in the vicinity of the active layer to confine the carrier injection and guide the light, respectively, in a lateral direction, current and light to be guided,
wherein the width of the waveguide region of the vertical cavity surface emitting laser and the width of the waveguide region of the electro-absorption modulator are determined according to the current confinement layer and/or the index guiding structure.

6. The surface emitting laser according to claim 5, wherein the current confinement layer is configured as a selectively-oxidized layer comprising an oxidized region selectively oxidized from a side face toward an inner side and an un-oxidized region surrounded by the oxidized region.

7. The surface emitting laser according to claim 5, wherein a high-resistance region is formed by means of ion injection as a boundary region that couples the current confinement layer of the vertical cavity surface emitting laser and the current confinement layer of the electro-absorption modulator.

8. The surface emitting laser according to claim 1, further comprising a metal mirror formed on the upper distributed Bragg reflector in a region in which the vertical cavity surface emitting laser is formed.

9. The surface emitting laser according to claim 1, wherein the number of layers of the upper distributed Bragg reflector in a region in which the electro-absorption modulator is formed is smaller than the number of layers of the upper distributed Bragg reflector in a region in which the vertical cavity surface emitting laser is formed.

10. The surface emitting laser according to claim 1, wherein the waveguide region has a width that is tapered in the second direction in a region that couples the vertical cavity surface emitting laser and the electro-absorption modulator.

11. A surface emitting laser comprising:
a vertical cavity surface emitting laser; and
an electro-absorption modulator,
wherein the vertical cavity surface emitting laser and the electro-absorption modulator are configured adjacent to each other in a first direction defined on a substrate plane such that they have a common layer structure comprising a semiconductor substrate, a lower distributed Bragg reflector, an active layer, and an upper distributed Bragg reflector, and wherein a width of a waveguide region included in the vertical cavity surface emitting laser, defined in a second direction that is orthogonal to the first direction defined on the substrate plane, is narrower than a width of a waveguide region of the electro-absorption modulator defined in the second direction.
